(19) United States
(12) Patent Application Publication
(10) Pub. No.: US 2025/0357720 A1
(43) Pub. Date: Nov. 20, 2025

(54) LIGHT SOURCE APPARATUS

(71) Applicant: Lasertec Corporation, Yokohama (JP)

(72) Inventors: Yosuke ORII, Yokohama-shi (JP); Keitaro HAYASHIDA, Yokohama-shi (JP); Masaki KOICHI, Yokohama-shi (JP)

(21) Appl. No.: 19/205,768

(22) Filed: May 12, 2025

(30) Foreign Application Priority Data
May 20, 2024 (JP) 2024-081512

(51) Int. Cl. H01S 3/10

(52) U.S. Cl. CPC H01S 3/10023; H01S 3/10092

(57) ABSTRACT

A light source apparatus according to the present disclosure includes a target holding unit configured to hold a target material on an inner wall surface with a centrifugal force caused by rotation around a rotation axis, a laser configured to excite the target material with a ray that is based on amplified light amplified by an amplifier, and a switch provided between the amplifier and the target material or an element group exhibiting a nonlinear optical effect provided between the amplifier and the target material. The light switch or the element group suppresses a power component in the amplified light which is equal to or smaller than a predetermined threshold, and the target material generates plasma with a ray in which the power component is suppressed.

### INCORPORATION BY REFERENCE

This application is based upon and claims the benefit of priority from Japanese patent application No. 2024-081512, filed on May 20, 2024, the disclosure of which is incorporated herein in its entirety by reference for all purposes.

### BACKGROUND

The present disclosure relates to a light source apparatus.

Japanese Unexamined Patent Application Publication No. 2013-065804 describes a laser apparatus including an amplifier disposed on an optical path of pulse laser light, an optical shutter disposed on the optical path of the pulse laser light, and a controller that causes the optical shutter to open and close.

International Patent Publication No. WO 2014/119199 describes a laser apparatus including two or more amplifiers disposed on an optical path of pulse laser light and an optical isolator disposed between the amplifiers adjacent to each other on the optical path of the pulse laser light, the optical isolator suppressing transmission of light traveling from the amplifiers to a side on which a master oscillator is provided.

Japanese Patent No. 6968793 describes a device including a cylindrical symmetry element having a surface coated with a target material for plasma formation, a system that outputs a laser beam pulse train, and a pulse trimming unit that outputs a trimmed pulse that interacts with the target material to generate plasma.

### SUMMARY

An example of an object to be achieved by the present disclosure is to provide a light source apparatus that can improve stability of a ray with which a target material is irradiated. It should be noted that this object is only one of a plurality of objects to be achieved by a plurality of embodiments disclosed herein. Other objects or problems and new characteristics are clarified from the description of the present specification and the accompanying drawings.

A light source apparatus according to the present disclosure includes: a target holding unit configured to hold a target material on an inner wall surface with a centrifugal force caused by rotation around a rotation axis; a laser configured to excite the target material with a ray that is based on amplified light amplified by an amplifier; and a switch provided between the amplifier and the target material or an element group exhibiting a nonlinear optical effect provided between the amplifier and the target material. The switch or the element group suppresses a power component in the amplified light which is equal to or smaller than a predetermined threshold, and the target material generates plasma with a ray in which the power component is suppressed.

In the light source apparatus, the switch may take one of a first state and a second state in which the switch causes further suppression of propagation of the amplified light to the target material compared with the first state. The light source apparatus may further include a control unit configured to switch the first state and the second state of the switch at timing synchronized with a seed pulse.

In the light source apparatus, the element group may include: an element that converts a first wavelength of the amplified light input to the element into a second wavelength, power of transmitted light transmitted through the element being nonlinearly responding to power of the amplified light; and a filter provided at a post stage of the element and configured to suppress propagation of a component of the first wavelength of the transmitted light to the target material.

According to the present disclosure, it is possible to improve stability of a ray with which the target material is irradiated.

The above and other objects, features and advantages of the present disclosure will become more fully understood from the detailed description given hereinbelow and the accompanying drawings.

### BRIEF DESCRIPTION OF DRAWINGS

FIG. 1 is a sectional view illustrating a light source apparatus according to a first embodiment;

FIG. 2 is a perspective view illustrating a container functioning as a target holding unit in the light source apparatus according to the first embodiment;

FIG. 3 is a plan view illustrating the light source apparatus according to the first embodiment;

FIG. 4 is a diagram illustrating an acquiring unit, a driving unit, and a control unit in the light source apparatus according to the first embodiment;

FIG. 5 is a block diagram exemplifying a laser according to the first embodiment;

FIG. 6A is a graph illustrating time waveforms of lights in the laser;

FIG. 6B is a graph illustrating time waveforms of lights in the laser;

FIG. 6C is a graph illustrating time waveforms of lights in the laser;

FIG. 7 is a configuration diagram exemplifying an inspection apparatus including the light source apparatus according to the first embodiment;

FIG. 8 is a block diagram exemplifying a laser according to a second embodiment;

FIG. 9A is a graph illustrating time waveforms of lights in the laser;

FIG. 9B is a graph illustrating time waveforms of lights in the laser;

FIG. 9C is a graph illustrating time waveforms of lights in the laser;

FIG. 10A is a graph in which outputs from a light switch according to the first embodiment and outputs from an optical element according to the second embodiment are compared;

FIG. 10B is a graph in which outputs from a light switch according to the first embodiment and outputs from an optical element according to the second embodiment are compared; and

FIG. 10C is a graph in which outputs from a light switch according to the first embodiment and outputs from an optical element according to the second embodiment are compared.

### DESCRIPTION OF EMBODIMENTS

A specific configuration of an embodiment is explained below with reference to the drawings. The following explanation indicates a preferred embodiment of the present disclosure. The scope of the present disclosure is not limited to the embodiment explained below. In the following explanation, those with the same reference numerals and signs indicate substantially the same content.

### First Embodiment

A light source apparatus according to a first embodiment is explained. The light source apparatus in the present embodiment generates light such as illumination light and exposure light used for an optical apparatus such as an inspection apparatus and an exposure apparatus. The light source apparatus may be provided integrally with the optical apparatus or may be disposed near the optical apparatus as a separate body separated from the optical apparatus. When the optical apparatus is the inspection apparatus, the light source apparatus generates illumination light for illuminating an inspection target in the inspection apparatus. When the optical apparatus is the exposure apparatus, the light source apparatus generates exposure light for exposing an exposure target in the exposure apparatus.

The light source apparatus irradiates a target material held by a target holding unit with excitation light to thereby generate light such as illumination light and exposure light. In the first embodiment explained below, as an example of the light source apparatus, an example in which a liquid target material is held in a target holding unit including a container such as a crucible is explained. However, the target holding unit may include a cylindrical drum or the like rather than the container such as a crucible. For example, a solid target material is held in the drum. As another example, the light source apparatus may use a tape-like target material or may use a target material dripped or spouted in a droplet shape. That is, the target holding unit is not always necessary in the configuration of the light source apparatus.

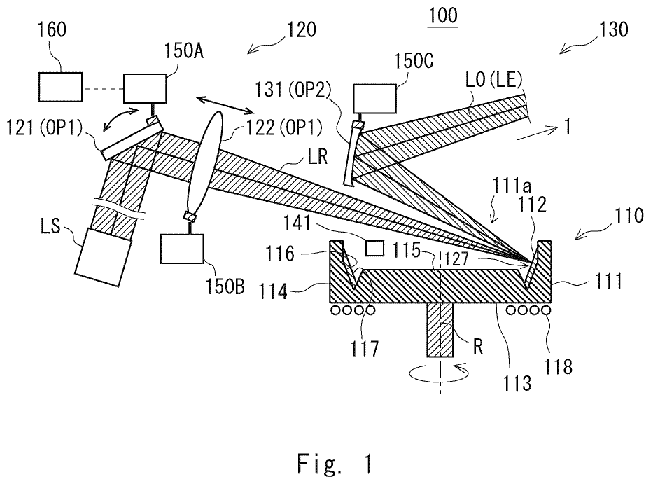

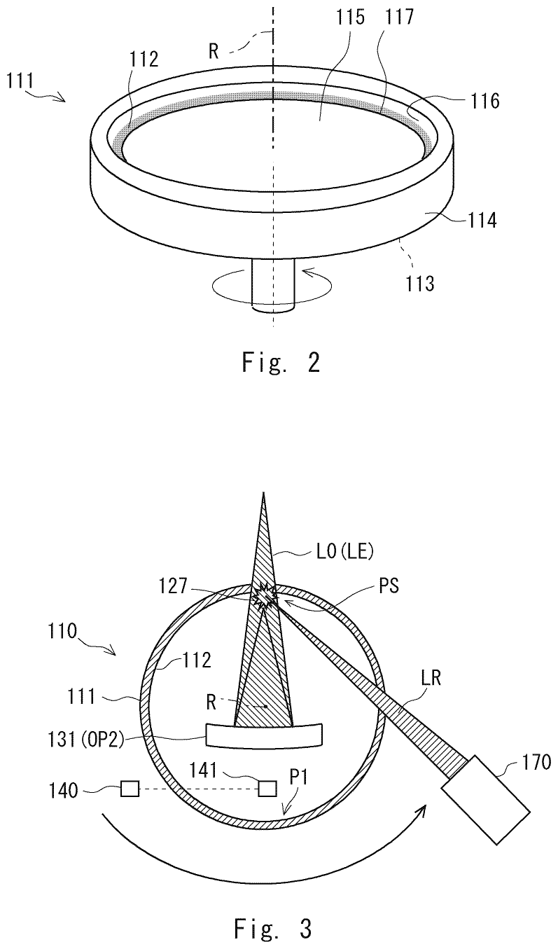

FIG. 1 is a sectional view illustrating a light source apparatus 100 according to the first embodiment. FIG. 2 is a perspective view illustrating a container 111 functioning as a target holding unit 110 in the light source apparatus 100 according to the first embodiment. FIG. 3 is a plan view illustrating the light source apparatus 100 according to the first embodiment. In FIG. 3, several members are omitted. As illustrated in FIGS. 1 to 3, the light source apparatus 100 includes a target holding unit 110, an input optical system 120, an output optical system 130, an acquiring unit 140, a sensor 141, a driving unit 150, and a control unit 160. The control unit 160 controls the members of the light source apparatus 100. The control unit 160 includes, for example, a processor. As the processor, as an example, one of a CPU (Central Processing Unit), an MPU (Micro Processing Unit), an FPGA (Field-Programmable Gate Array), and an ASIC (Application Specific Integrated Circuit) may be used. Alternatively, the control unit 160 may include a plurality of processors. A storage apparatus (not illustrated) connected to the processor stores, as a program, processing to be executed by the light source apparatus 100. The processor executes the program by causing a memory (not illustrated) to read the program stored in the storage apparatus. Accordingly, the processor implements functions of the components in the light source apparatus 100. Note that the control unit 160 may be an information processing apparatus including a processor, a memory, and a storage apparatus. The information processing apparatus may be, for example, a PC (Personal Computer), a server, or a microcomputer. In FIG. 1, a driving unit 150A is connected to a mirror 121, a driving unit 150B is connected to a condensing lens 122, and a driving unit 150C is connected to a collector mirror 131. However, the driving units do not always need to be connected to all of these optical members. The control unit 160 is connected to only several members to prevent the figure from becoming complicated. However, the control unit 160 may be connected to other members.

The target holding unit 110 holds a target material 112. The target holding unit 110 includes a container 111 such as a melting pot. The container 111 can melt metal inside. The container 111 holds the target material 112 such as molten metal that generates plasma 127 with irradiation of excitation light LR. The excitation light LR is, for example, laser light including IR (Infrared) light.

Note that the target holding unit 110 is not limited to the container 111 and may be a cylindrical drum. In that case, the target holding unit 110 holds the target material 112 by fixing solid, which becomes the target material 112, such as xenon (Xe) frozen on the surface of the drum.

The target material 112 may include molten metal. Note that the target material 112 is not limited to the molten metal held by the container 111 and may be solid metal, droplets, or the like if the target material 112 is a substance that generates the plasma 127 with irradiation of the excitation light LR. The molten metal is, for example, melted tin (Sn) or lithium (Li) but is not limited to tin and lithium if the molten metal generates the plasma 127 with irradiation of the excitation light LR.

The container 111 has a rotation axis R and rotates centering on the rotation axis R. The container 111 has, for example, a cylindrical shape with one opening closed. A closed portion of the container 111 is referred to as bottom 113. A cylindrical portion of the container 111 is referred to as cylindrical section 114. The surface on the inner side of the bottom 113 is referred to as bottom surface 115. The surface on the inner side of the cylindrical section 114 is referred to as inner wall surface 116. A groove 117 may be formed in a joining portion of the bottom 113 and the cylindrical section 114. Note that the container 111 may include a shape other than the above if the container 111 can hold the molten metal.

The target holding unit 110 supports the target material 112 on the inner wall surface 116 of the container 111 with a centrifugal force. The inner wall surface 116 formed to surround the rotation axis R may include a cylindrical portion having a constant distance to the rotation axis R or may include a cone-shaped portion further expanded to the outer side upward. For example, the cone-shaped portion of the inner wall surface 116 may be connected to the groove 117.

The target material 112 also rotates around the rotation axis R according to the rotation of the container 111 around the rotation axis R. As illustrated in FIG. 3, for example, the target material 112 located, at time t1, in a position P1 facing the sensor 141 moves to an irradiation position PS at time t2 according to the rotation of the container 111. In this way, according to the movement (that is, the rotational movement) of the target holding unit 110, the target holding unit 110 moves the target material 112 to the irradiation position PS where the target material 112 is irradiated with the excitation light LR.

The input optical system 120 includes a first optical member OP1. The first optical member OP1 irradiates the target material 112 with the excitation light LR. The first optical member OP1 includes, for example, at least one of a mirror 121 and a condensing lens 122. Note that the first optical member OP1 is not limited to the mirror 121 and the condensing lens 122 if the first optical member OP1 is an optical member that irradiates the target material 112 with the excitation light LR. The first optical member OP1 may be a laser LS that generates the excitation light LR.

The mirror 121 reflects, for example, the excitation light LR generated by the laser LS to the irradiation position PS of the target material 112. The mirror 121 may include a mirror such as a piezo steering mirror. Note that, the mirror 121 is not limited to the piezo steering mirror and may include a Galvano mirror, a polygon mirror, and the like if the mirror 121 can reflect the excitation light LR to the target material 112. The condensing lens 122 condenses the excitation light LR on the irradiation position PS of the target material 112.

The light source apparatus 100 may include the laser LS that generates the excitation light LR. On the other hand, the light source apparatus 100 may introduce, into the light source apparatus 100, the excitation light LR from the laser LS installed separately from the light source apparatus 100 on the outside of the light source apparatus 100. The excitation light LR is, for example, laser light including IR light. The excitation light LR may irradiate the target material 112 according to oscillation and stop of control of the control unit 160. For example, the excitation light LR is reflected by the mirror 121 and condensed by the condensing lens 122. Accordingly, the excitation light LR irradiates the target material 112. Note that a detailed configuration of the laser LS is explained below.

The output optical system 130 includes a second optical member OP2. The second optical member OP2 extracts, from the light source apparatus 100, light L0 generated by irradiating the target material 112 with the excitation light LR. The second optical member OP2 includes, for example, the collector mirror 131. Note that the second optical member OP2 is not limited to the collector mirror 131 if the second optical member OP2 is an optical member that extracts light L0 generated by irradiating the target material 112 with the excitation light LR. The second optical member OP2 may be a second collector mirror (not illustrated) that further reflects the light L0 reflected by the collector mirror 131.

The collector mirror 131 reflects the light L0 generated from the target material 112 by the irradiation of the excitation light LR. The collector mirror 131 reflects, for example, EUV (Extreme Ultraviolet Lithography) light LE generated by the irradiation of the excitation light LR. That is, the light L0 may include the EUV light LE. The EUV light LE is generated from the plasma 127 generated by irradiating the target material 112 with the excitation light LR. The EUV light LE generated from the plasma 127 generated by the target material 112 is emitted to an optical apparatus such as an inspection apparatus as illumination light. Thus, the illumination light includes the EUV light generated from the plasma 127.

The acquiring unit 140 acquires a surface position of the target material 112. The acquiring unit 140 is connected to the sensor 141 and acquires, from the sensor 141, a surface position of the target material 112 measured by the sensor 141. The acquiring unit 140 acquires a surface position of the target material 112 in the irradiation position PS where the excitation light LR irradiates the target material 112. The acquiring unit 140 may acquire a surface position measured by the sensor 141 in the irradiation position PS or, as explained below, may predict a surface position in the irradiation position PS from a surface position measured by the sensor 141 in a peripheral position. The acquiring unit 140 may predict the surface position of the target material 112 considering a tilt with respect to the rotation axis and vibration of the target holding unit 110.

The acquiring unit 140 may be a separate body separated from the sensor 141 or may be integrated with the sensor 141. Specifically, the sensor 141 may include, for example, a displacement meter, a high-speed camera, a low-speed camera, a quadripartite PD (Photo Diode), and a TDI (Time Delay Integration) camera. The acquiring unit 140 may combine other sensors with the sensor 141 such as the displacement meter to thereby acquire the surface position of the target material 112. Accordingly, the other sensors can supplement phase information that the sensor 141 such as the displacement meter cannot easily acquire.

The acquiring unit 140 may acquire the surface position of the target material 112 as a relative position to the second optical member OP2. Specifically, the acquiring unit 140 may acquire the surface position in the irradiation position PS of the target material 112 as the relative position to the second optical member OP2 or may acquire the surface position in the peripheral position as the relative position to the second optical member OP2. The acquiring unit 140 may acquire the surface position of the target material 112 based on the distance from the sensor 141 to the surface of a liquid surface of molten metal. The acquiring unit 140 may acquire the surface position of the target material 112 based on the thickness of the liquid surface of the molten metal from the inner wall surface 116. Note that, when the target material 112 is solid metal fixed to a cylindrical drum, the acquiring unit 140 may acquire the surface position of the target material 112 based on a tilt and a vibration amount of the drum besides the thickness of the surface of the solid metal from the upper surface (the uppermost surface) of the drum.

The acquiring unit 140 may acquire a surface position in a peripheral position other than the irradiation position PS. The peripheral position includes a portion other than the irradiation position PS on the inner wall surface 116 of the container 111. The acquiring unit 140 may predict the surface position of the irradiation position PS from the surface position in the peripheral position acquired from the sensor 141. Specifically, the acquiring unit 140 predicts the surface position in the irradiation position PS from a surface position in a position on the near side of the irradiation position PS with respect to the direction of the movement of the target holding unit 110. At this time, considering moving speed (rotating speed) of the target holding unit 110, it is possible to predict the surface position in the irradiation position PS at a point in time (an irradiation point in time) when the excitation light reaches the irradiation position PS. The acquiring unit 140 predicts the surface position in the irradiation position PS in this way to thereby acquire the surface position in the irradiation position PS.

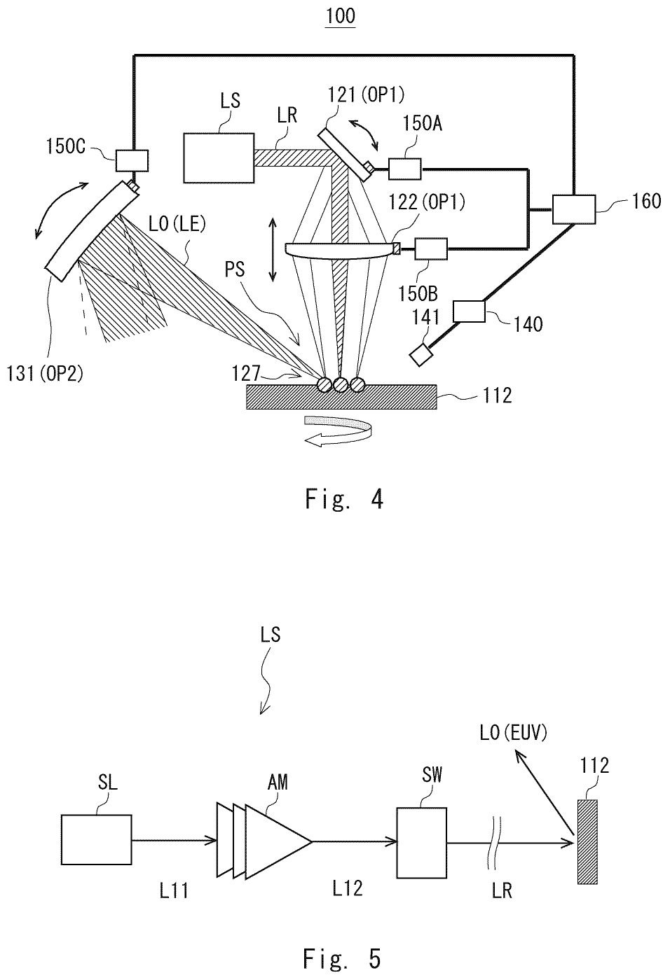

FIG. 4 is a diagram illustrating the acquiring unit 140, the driving unit 150, and the control unit 160 in the light source apparatus 100 according to the first embodiment. As explained above, the position of the sensor 141 is not limited to the position facing the irradiation position PS and may be a position facing the peripheral position such as the position P1. As illustrated in FIG. 4, the driving units 150A to 150C cause the position of the focusing point of at least one of the first optical member OP1 and the second optical member OP2 to vary. The driving units 150A to 150C are, for example, an actuator.

The driving units 150A and 150B drive the first optical member OP1 to change an irradiation direction of the excitation light LR. For example, when the first optical member OP1 is the mirror 121, the driving unit 150A swings an angle of the mirror 121 with respect to the excitation light LR to perform beam scan. Specifically, the driving unit 150A changes a reflection surface of the mirror 121 such that the excitation light LR scans the surface of the target material 112 in a predetermined direction.

When the mirror 121 is a piezo steering mirror, the driving unit 150A may include a driving mechanism provided in the piezo steering mirror. When the mirror 121 is a Galvano mirror, a polygon mirror, and the like, the driving unit 150A may be a driving mechanism provided in the Galvano mirror, the polygon mirror, and the like. Note that, when there is another actuator having a short response time and good controllability, the driving unit 150A may be the actuator.

The plasm 127 is generated in the irradiation position PS where the excitation light LR irradiates the target material 112. The generated plasma 127 is observed as a bright spot. The driving unit 150A drives the mirror 121 to fluctuate an optical axis of the excitation light LR and fluctuates the position of a focusing point. Accordingly, the driving unit 150A moves the bright spot at high speed to perform beam shaving. Thus, when the optical apparatus is an inspection apparatus, it is possible to improve uniformity and availability on a detector of the inspection apparatus. The driving unit 150A may cause the position of the focusing point to vary in two axial directions on the surface of the target material 112 in the irradiation position PS.

FIG. 5 is a block diagram exemplifying the laser LS according to the first embodiment. As illustrated in FIG. 5, the laser LS includes a seed laser SL, a light amplifier AM, and a light switch SW. In the laser LS, the seed laser SL, the light amplifier AM, and the light switch SW are disposed in order from a pre-stage to a post stage.

The seed laser SL outputs, based on the control of the control unit 160, seed light L11 before being amplified by the light amplifier AM. The light amplifier AM amplifies the input seed light L11 and outputs amplified light L12. One or more light amplifiers AM are provided according to necessity. The light switch SW suppresses a power component (a low power component) in the amplified light L12 which is equal to or smaller than a predetermined threshold output from the light amplifier AM as explained below and outputs, to the target material 112, the excitation light LR in which the low power component is suppressed. Note that, in FIG. 5, the mirror 121 and the condensing lens 122 provided on an optical path of the excitation light LR are not illustrated.

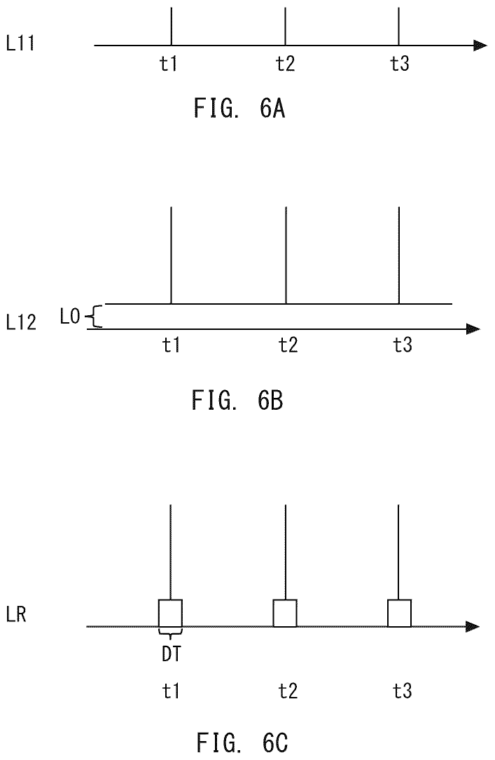

FIGS. 6A to 6C are graphs illustrating time waveforms of lights in the laser LS. In FIG. 6A, the seed light L11 has pulse components at hours t1, t2, and t3. The pulse components are amplified by the light amplifier AM. At this time, as illustrated in FIG. 6B, a low power component L0 other than the pulse components is included in the amplified light L12. The low power component L0 is a component having power equal to or smaller than a predetermined threshold and is, for example, a component having power smaller than power suitable for converting the target material 112 into plasma. The light switch SW is controlled by the control unit 160 to be in an ON state at the hours t1, t2, and t3 when the pulse components are output (that is, timings synchronized with the seed pulse) and transmits light and, in contrast, to be in an OFF state at the other hours and not to transmit light. In other words, the light switch SW is controlled in synchronization with hours of the pulse components. Accordingly, a component of the amplified light L12 is transmitted at the hours t1, t2, and t3 and in switch drive times DT at the hours and the component of the amplified light L12 is not transmitted at the other hours. Therefore, as illustrated in FIG. 6C, an amplified pulse component remains in the excitation light LR and, on the other hand, a low power component is suppressed. Note that the wavelength of the amplified light L12 and the wavelength of the excitation light LR are the same.

Note that the light switch SW may be configured to transmit light when being in the OFF state and not to transmit light when being in the ON state. In the example explained above, an example in which the light switch SW controls the transmission of the amplified light L12 according to ON and OFF is explained. However, the light switch SW is not limited to this. That is, according to the switching of the ON state and the OFF state, the light switch SW may, for example, (1) switch to a first state in which the amplified light L12 is diffracted or reflected at a predetermined angle to the target material 112 and a second state in which the amplified light L12 is transmitted, absorbed, or diffracted or reflected at an angle different from the predetermined angle or (2) switch to a first state in which a polarization state of the amplified light L12 is changed and the amplified light L12 is propagated to the target material 112 via a polarization plate or a polarization beam splitter and a second state in which the propagation of the amplified light L12 to the target material 112 is suppressed. Both of (1) and (2) are examples for the light switch SW to take one of the first state in which the amplified light L12 is propagated to the target material 112 as the excitation light LR and the second state in which the propagation of the amplified light L12 to the target material 112 is further suppressed compared with the first state.

### <Optical Apparatus>

Subsequently, the optical apparatus is explained. The optical apparatus is explained using an inspection apparatus as an example of the optical apparatus.

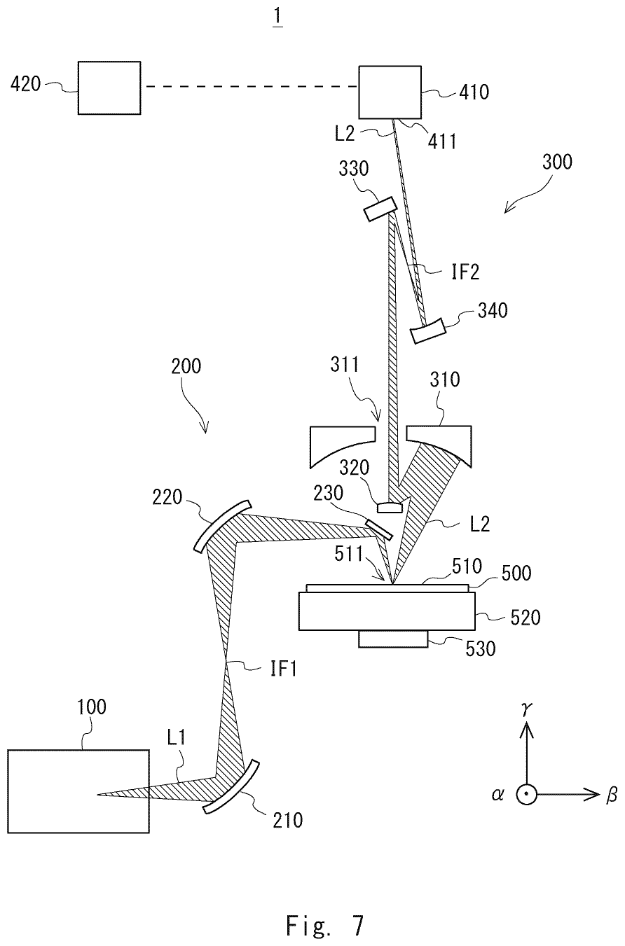

FIG. 7 is a configuration diagram illustrating an inspection apparatus 1 including the light source apparatus 100 according to the first embodiment. As illustrated in FIG. 7, the inspection apparatus 1 includes an illumination optical system 200, an inspection optical system 300, a detector 410, and an image processing unit 420. Note that the inspection apparatus 1 may further include the light source apparatus 100. The inspection apparatus 1 is an apparatus that inspects a defect and the like of a sample 500 using, as the illumination light L1, the light L0 generated by the light source apparatus 100. The sample 500 is, for example, an EUV mask. Note that the sample 500 is not limited to the EUV mask and may be a semiconductor substrate or the like.

The illumination optical system 200 includes an ellipsoidal mirror 210, an ellipsoidal mirror 220, and a drop-in mirror 230. The inspection optical system 300 includes a concave mirror with hole 310, a convex mirror 320, a plane mirror 330, and a concave mirror 340. The concave mirror with hole 310 and the convex mirror 320 configure a Schwarzschild enlarging optical system.

The light source apparatus 100 generates illumination light L1. The illumination light L1 includes, for example, the EUV light LE having a wavelength of 13.5 nm that is the same as an exposure wavelength of the EUV mask to be the sample 500. Note that the illumination light L1 may include light other than the EUV light. The illumination light L1 generated from the light source apparatus 100 is reflected by the ellipsoidal mirror 210. The illumination light L1 reflected by the ellipsoidal mirror 210 travels while being narrowed and is condensed at a convergent point IF1. Thus, the ellipsoidal mirror 210 reflects, as convergent light, the illumination light L1 generated from the light source apparatus 100. The convergent point IF1 is a position conjugate with an upper surface 510 of the sample 500 such as the EUV mask and a detection surface 411 of the detector 410.

After passing the convergent point IF1, the illumination light L1 travels while expanding and is made incident on a reflection mirror such as the ellipsoidal mirror 220. Thus, the illumination light L1 reflected by the ellipsoidal mirror 210 is made incident on the ellipsoidal mirror 220 as divergent light via the convergent point IF1. The illumination light L1 made incident on the ellipsoidal mirror 220 is reflected by the ellipsoidal mirror 220, travels while being narrowed, and is made incident on the drop-in mirror 230. That is, the ellipsoidal mirror 220 reflects the incident illumination light L1 as convergent light. The ellipsoidal mirror 220 makes the illumination light L1 incident on the drop-in mirror 230. The drop-in mirror 230 is disposed right above the EUV mask. The illumination light L1 made incident on the drop-in mirror 230 and reflected is made incident on the sample 500. Thus, the drop-in mirror 230 makes the illumination light L1 incident on the sample 500 by reflecting, to the sample 500, the illumination light L1 reflected by the ellipsoidal mirror 220.

The ellipsoidal mirror 220 condenses the illumination light L1 on the sample 500. The illumination optical system 200 is installed to form an image of the light source apparatus 100 on the upper surface 510 of the sample 500 when the illumination light L1 illuminates the sample 500. Thus, the illumination optical system 200 is critical illumination. As explained above, the illumination optical system 200 illuminates the sample 500 such as the EUV mask using the critical illumination by the illumination light L1 generated by the light source apparatus 100.

The sample 500 is disposed on a stage 520. Here, a plane parallel to the upper surface 510 of the sample 500 is represented as αβ plane and a direction perpendicular to the αβ plane is represented as y-axis direction. The illumination light L1 is made incident on the sample 500 from a direction tilting from the y-axis direction. That is, the illumination light L1 is made obliquely incident and illuminates the sample 500.

The stage 520 is a three-dimensional driving stage including a driving unit 530. The driving unit 530 can illuminate a desired region of the sample 500 by moving the stage 520 in the αβ plane. Further, the driving unit 530 can perform focus adjustment by moving the stage 520 in the y-axis direction.

The illumination light L1 from the light source apparatus 100 illuminates an inspection region of the sample 500. The inspection region illuminated by the illumination light L1 is, for example, a 0.5 mm square. Note that the inspection region is not limited to the 0.5 mm square. The illumination light L1 is made incident on the sample 500 from a direction tilted with respect to the y-axis direction. Light from the sample 500 illuminated by the illumination light L1 is made incident on the concave mirror with hole 310. In the following explanation, the light from the sample 500 illuminated by the illumination light L1 is explained as reflected light L2. Note that the light made incident on the concave mirror with hole 310 from the sample 500 is not limited to the reflected light L2 and may include diffracted light or the like. The reflected light L2 reflected by the sample 500 is made incident on the concave mirror with hole 310. A hole 311 is provided in the center of the concave mirror with hole 310. The concave mirror with hole 310 condenses the reflected light L2 from the sample 500 and reflects the condensed reflected light L2 as convergent light.

The reflected light L2 reflected by the concave mirror with hole 310 is made incident on the convex mirror 320. The convex mirror 320 reflects the reflected light L2 reflected by the concave mirror with hole 310 toward the hole 311 of the concave mirror with hole 310. The reflected light L2 having passed through the hole 311 is made incident on the plane mirror 330. The plane mirror 330 makes the reflected light L2 reflected by the convex mirror 320 incident as convergent light through the hole 311 of the concave mirror with hole 310. The reflected light L2 made incident on the plane mirror 330 is reflected by the plane mirror 330. The reflected light L2 reflected by the plane mirror 330 travels while being narrowed and is condensed at a convergent point IF2. Thus, the plane mirror 330 reflects the incident reflected light L2 as convergent light. The convergent point IF2 may be referred to as aperture stop. The convergent point IF2 is a position conjugate with the upper surface 510 of the sample 500 and the detection surface 411 of the detector 410.

After passing the convergent point IF2, the reflected light L2 travels while expanding and is made incident on the concave mirror 340. Thus, the reflected light L2 reflected by the plane mirror 330 as the convergent light is made incident on the concave mirror 340 via the focusing point IF2 as divergent light. The concave mirror 340 reflects the incident reflected light L2 to the detector 410 as convergent light. The reflected light L2 reflected by the concave mirror 340 is detected by the detector 410. As explained above, the inspection optical system 300 inspects the sample 500, which is the inspection target, with the light L1 extracted from the output optical system 130 of the light source apparatus 100. That is, the inspection optical system 300 condenses the reflected light L2 from the sample 500 illuminated by the illumination light L1 and guides the condensed reflected light L2 to the detector 410.

The detector 410 may include a TDI (Time Delay Integration) sensor. The detector 410 receives light from the sample 500 illuminated by the illumination light L1. A region on the sample 500 detected by the detector 410 is referred to as visual field region 511. The detector 410 receives the reflected light L2 from the visual field region 511 illuminated by the illumination light L1. The visual field region 511 may be included in the inspection region illuminated by the illumination light L1. The detector 410 acquires image data of the sample 500 such as the EUV mask. When the detector 410 includes a TDI sensor, the detector 410 includes a plurality of imaging elements linearly disposed side by side in one direction. The imaging elements are, for example, CCDs (Charge Coupled Devices). Note that the imaging elements are not limited to the CCDs.

The image data of the sample 500 acquired by the detector 410 is output to the image processing unit 420 and processed in the image processing unit 420. The image processing unit 420 may be, for example, a server apparatus or an information processing apparatus such as a personal computer.

The reflected light L2 includes information concerning a defect or the like of the sample 500. Regular reflected light of the illumination light L1 made incident on the sample 500 from a direction tilted with respect to the Z-axis direction is detected by the inspection optical system 300. When a defect is present in the sample 500, the defect is observed as a dark image. Such an observation method is referred to as bright field observation. Note that the inspection apparatus 1 may make the illumination light L1 incident on the sample 500 from the Z-axis direction and cause the inspection optical system 300 to detect the illumination light L1. When a defect is present in the sample 500, the defect is observed as a bright image. Such an observation method is referred to as dark field observation.

As explained above, the inspection apparatus 1 in the present embodiment includes the light source apparatus 100 explained above and the inspection optical system 300 that inspects an inspection target with the light L0 extracted from the output optical system 130. Note that the inspection apparatus 1 is explained as the optical apparatus. However, the optical apparatus may be an exposure apparatus. For example, the exposure apparatus includes the light source apparatus 100 explained above and an exposure optical system that exposes an exposure target with the light L0 extracted from the output optical system 130. The control unit 160 may drive the driving unit 150 such that the light L0 scans an exposure region in the exposure target.

As explained above, the light switch SW in the laser LS suppresses the low power component in the excitation light LR with which the target material 112 is irradiated. In other words, the light switch SW suppresses the propagation of low power components (below a predetermined threshold) in the amplified light L12 output from the optical amplifier AM to the target material 112. For that reason, the stability of the excitation light LR is improved and the luminance of the plasma 127 to be generated is stabilized. Therefore, a stable detection result can be obtained in the detector 410.

### Second Embodiment

A light source apparatus according to a second embodiment is explained. In the present embodiment, a configuration of a laser having a configuration different from the configuration of the laser LS according to the first embodiment is explained. In the second embodiment, the element group EG exhibiting a nonlinear optical effect suppresses the propagation of low power components (below a predetermined threshold) in the amplified light L12 output from the optical amplifier AM to the target material 112.

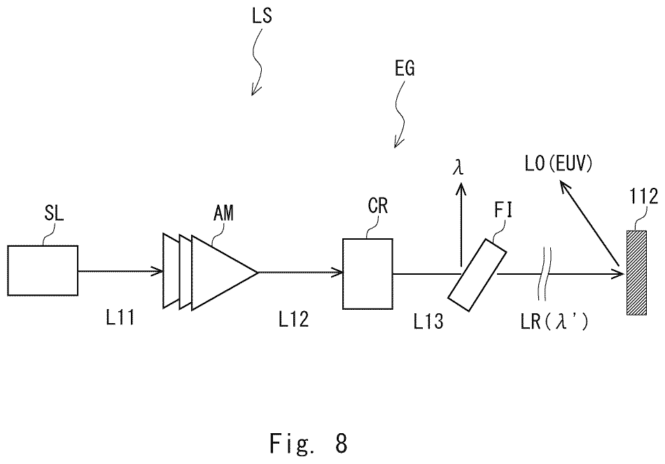

FIG. 8 is a block diagram exemplifying the laser LS according to the second embodiment. As illustrated in FIG. 8, the laser LS includes the seed laser SL, the light amplifier AM, an optical element CR, and a filter F1. The optical element CR and the filter F1 are also called element group EG exhibiting a nonlinear optical effect. In the laser LS, the seed laser SL, the light amplifier AM, the optical element CR, and the filter F1 are disposed in order from a pre-stage to a post stage.

Since explanation of the seed laser SL and the light amplifier AM is the same as the explanation in the first embodiment, the explanation is omitted. The optical element CR is configured by a crystal exhibiting a nonlinear optical effect and causes an event such as stimulated Raman scattering or harmonic generation to emit light having a wavelength different from the wavelength of the amplified light L12 that is incident light. In other words, power of nonlinear light L13 transmitted through the optical element CR nonlinearly responds to power of the amplified light L12. The stimulated Raman scattering is caused by a crystal such as YVO4 or KGW and the harmonic generation is caused by a crystal such as LBO, KTP, or BBO. Wavelength conversion efficiency between incident light and outgoing light in the optical element CR depends on power of laser light made incident on the optical element CR. In the optical element CR, wavelength conversion is less easily performed in a time period of low power in the incident light and is easily performed in a time period of high power. For that reason, the optical element CR converts the wavelength of a high power component of the amplified light L12 and outputs the high power component and, on the other hand, does not convert the wavelength of a low power component of the amplified light L12 and outputs the low power component. In the following explanation, a wavelength before being converted by the optical element CR is represented as λ and a wavelength after the conversion is represented as N′. The filter F1 suppresses transmission of light having the wavelength A in the nonlinear light L13 output by the optical element CR and transmits light having the wavelength λ′ to output the excitation light LR.

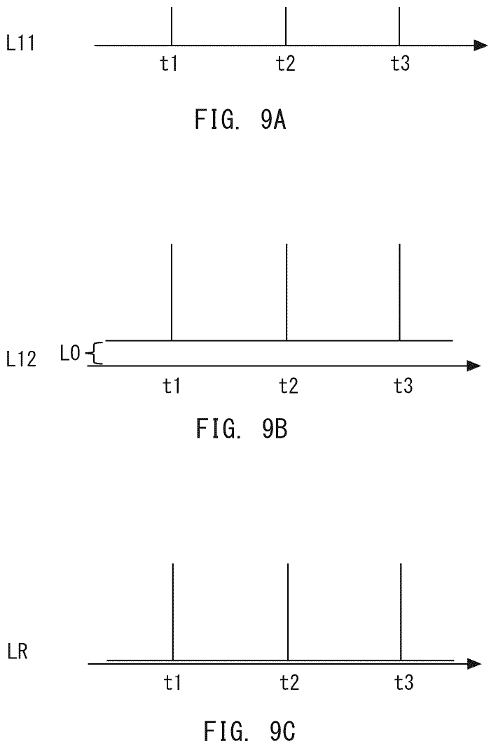

FIGS. 9A to 9C are graphs illustrating time waveforms of lights in the seed laser SL. In FIG. 9A, the seed light L11 has pulse components at the hours t1, t2, and t3. As explained in the first embodiment, the pulse components are amplified by the light amplifier AM. As illustrated in FIG. 9B, a low power component is included in the amplified light L12 at this time. The low power component is a component having power equal to or smaller than a predetermined threshold and is, for example, a component having power smaller than power suitable for converting the target material 112 into plasma. The optical element CR outputs the nonlinear light L13 in which a wavelength is converted in a time when a pulse component, which is a high power component of the amplified light L12, is present and the conversion of the wavelength is suppressed in a time in which the low power component L0 is present. The filter F1 outputs the excitation light LR to transmit the high power component of the amplified light L12 having the wavelength A′ and suppress transmission of the low power component of the amplified light L12 having the wavelength λ. Therefore, as illustrated in FIG. 9C, the excitation light LR is in a state in which the low power component L0 is suppressed.

As explained above, since the optical element CR and the filter F1 that perform the wavelength conversion are provided in the laser LS, it is possible to transmit a pulse component of laser and suppress transmission of a low power component other than the pulse component. For that reason, since the stability of the excitation light LR is improved and the luminance of the plasma 127 to be generated is stabilized, it is possible to obtain a stable detection result in the detector 410. Unlike the first embodiment, synchronization control for the optical element CR and the filter F1 with a laser pulse by the control unit 160 is unnecessary. For that reason, it is possible to design the laser LS with a simpler configuration. Note that, in the above explanation, the filter F1 is explained as transmitting the high power component of the amplified light L12 having the wavelength A′ and suppressing transmission of the low power component of the amplified light L12 having the wavelength λ. However, functions of the filter F1 are not limited to this. The filter F1 reflects the high power component of the amplified light L12 having the wavelength A′ at a predetermined reflection angle, whereby the high power component of the reflected amplified light L12 may be propagated toward the target material 112 as the excitation light LR and, on the other hand, the low power component of the amplified light L12 may be, for example, transmitted or absorbed by the filter F1. This is also an example of the filter F1 for suppressing the propagation of the low power component of (a first wavelength component of) the amplified light L12 to the target material 112.

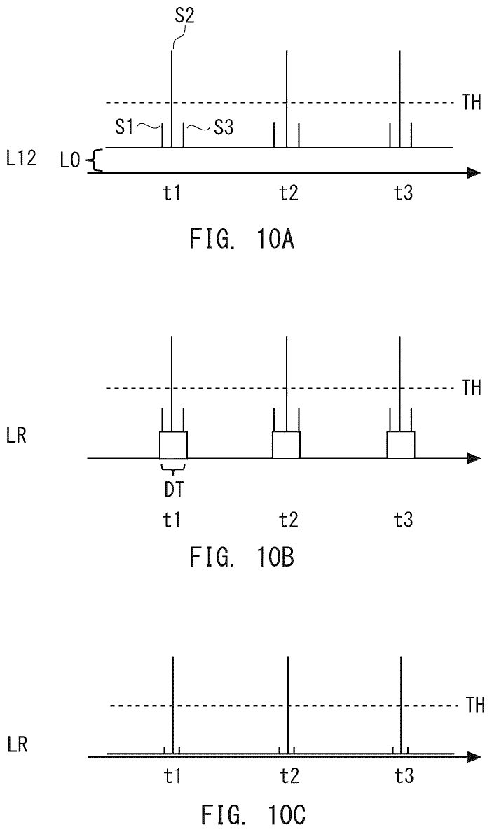

Further, when the low power component is included near the high power component in the amplified light L12 output by the light amplifier AM, for example, when at least one of a pre-pulse and a post pulse having low power is included near a main pulse, it is sometimes advantageous to use the optical element CR as in the second embodiment. This is explained with reference to FIGS. 10A to 10C.

FIG. 10A illustrates a waveform of the amplified light L12. The amplified light L12 near the hours t1, t2, and t3 includes a pre-pulse S1, a main pulse S2, and a post pulse S3. The pre-pulse S1 and the post pulse S3 are located temporally near the main pulse S2. Power of the pre-pulse S1 and the post pulse S3 is smaller than a threshold TH that is a threshold for determining high power or low power. Power of the main pulse S2 is larger than the threshold TH. FIG. 10B illustrates a waveform at the time when the low power component L0 is suppressed using the light switch SW according to the example in the first embodiment in the amplified light L12 illustrated in FIG. 10A. FIG. 10C illustrates a waveform at the time when the low power component L0 is suppressed using the optical element CR according to the example in the second embodiment in the amplified light L12 illustrated in FIG. 10A.

As illustrated in FIG. 10B, a pre-pulse component and a post pulse component cannot be removed depending on the drive time DT of the light switch SW. There is a limit in reducing the drive time DT of the light switch SW. For that reason, when at least one of the pre-pulse component and the post pulse component occurs extremely near the main pulse and the component is included within a switch drive time together with the main pulse, such a low energy component sometimes cannot be removed by the light switch SW. On the other hand, as illustrated in FIG. 10C, the optical element CR can also suppress the pre-pulse and the post pulse extremely near the main pulse. This is because the optical element CR is a passive element and is quick in a time response.

Note that the light switch SW, the optical element CR, and the filter F1 only have to be provided downstream of the light amplifier AM. For that reason, the first optical member OP1 may include the light switch SW, the first optical element OP1 may include the filter F1, or the first optical member OP1 may include the optical element CR and the filter F1.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus comprising:
a target holding unit configured to hold a target material on an inner wall surface with a centrifugal force caused by rotation around a rotation axis;
a laser configured to excite the target material with a ray that is based on amplified light amplified by an amplifier; and
a switch provided between the amplifier and the target material or an element group exhibiting a nonlinear optical effect provided between the amplifier and the target material, wherein
the switch or the element group suppresses a power component in the amplified light which is equal to or smaller than a predetermined threshold, and
the target material generates plasma with a ray in which the power component is suppressed.

2. The light source apparatus according to claim 1, wherein
the switch takes one of a first state and a second state in which the switch causes further suppression of propagation of the amplified light to the target material compared with the first state, and
the light source apparatus further includes a control unit configured to switch the first state and the second state of the switch at timing synchronized with a seed pulse.

3. The light source apparatus according to claim 1, wherein the element group includes:
an element that converts a first wavelength of the amplified light input to the element into a second wavelength, power of transmitted light transmitted through the element being nonlinearly responding to power of the amplified light; and
a filter provided at a post stage of the element and configured to suppress propagation of a component of the first wavelength of the transmitted light to the target material.
